(19) United States
(12) Patent Application Publication
(10) Pub. No.: US 2014/0361799 A1
(43) Pub. Date: Dec. 11, 2014

(54) APPARATUS FOR TEMPERATURE CONTROLLED ELECTRICAL AND OPTICAL PROBE FAULT CHARACTERIZATION OF INTEGRATED CIRCUITS

(71) Applicant: QUALCOMM Incorporated, San Diego, CA (US)

(72) Inventors: Armand Anthony Graupera, San Diego, CA (US); Himaja Hardik Bhatt, San Diego, CA (US); Joanna Kiljan, San Diego, CA (US); Lesly Zaren V. Endrinal, San Diego, CA (US); Martin L. Villafana, San Diego, CA (US); Ulrike Kindereit, San Diego, CA (US)

(73) Assignee: QUALCOMM Incorporated, San Diego, CA (US)

(21) Appl. No.: 14/142,721

(22) Filed: Dec. 27, 2013

Related U.S. Application Data
(60) Provisional application No. 61/831,609, filed on Jun. 5, 2013.

(51) Int. Cl. G01R 31/28

(52) U.S. Cl. CPC G01R 31/2874
USPC 324/750.11

(57) ABSTRACT

An apparatus includes an electrically insulating thermally conductive carrier for supporting a device under test (DUT), one or more thermo-electric devices arranged with the carrier, and one or more conductive vias in the carrier to make electrical connection to the DUT for coupling to an external test apparatus. A method of testing a device under test (DUT) includes supporting the DUT on an electrically insulating thermally conductive carrier, arranging one or more thermo-electric devices coupled to the carrier to control the temperature of the DUT, connecting the DUT electrically to an external test apparatus through one or more conductive vias in the carrier, connecting the one or more thermo-electric devices to the external test apparatus, and characterizing with the external apparatus the DUT on the basis of the temperature of the DUT.

### CROSS-REFERENCE TO RELATED APPLICATIONS

This application is related to and claims priority from U.S. Provisional Patent Application Ser. No. 61/831,609 filed Jun. 5, 2013, for “INTEGRATED, SOLID STATE, PRECISION TEMPERATURE CONTROL SOLUTION FOR USE WITH A DUT ON FAILURE ANALYSIS EQUIPMENT.”

### TECHNICAL FIELD

The present disclosure relates to testing electronic devices. More specifically, the present disclosure relates to testing and characterizing failed devices under controlled temperature conditions on automatic test equipment (ATE) for failure analysis.

### BACKGROUND

Electronic devices (cellular telephones, wireless modems, computers, digital music players, Global Positioning System units, Personal Digital Assistants, gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of digital circuits to support the processor and other parts of the device.

Many different kinds of electronic devices may benefit from testing. Types of such devices include, but are not limited to, cellular telephones, wireless modems, computers, digital music players, Global Positioning System units, Personal Digital Assistants, gaming devices, etc. One group of devices includes those that may be used with wireless communication systems. As used herein, the term “mobile station” refers to an electronic device that may be used for voice and/or data communication over a wireless communication network. Examples of mobile stations include cellular phones, handheld wireless devices, wireless modems, laptop computers, personal computers, etc. A mobile station may alternatively be referred to as an access terminal, a mobile terminal, a subscriber station, a remote station, a user terminal, a terminal, a subscriber unit, user equipment, etc.

Advanced cellular handsets include a multiplicity of individual or stacked IC devices, such as a modem, power management chip, RF transmitter/receiver, video processor and a microprocessor, among others. All or some of these devices may exist in a single chip or in a single package. With increased demand for high bandwidth, high speed wireless services, today's high performance cellular IC's are required to operate at increasingly higher speeds within an ever smaller handheld package. Significant amounts of heat may be generated, at times up to 60 W, by such devices during peak operation, resulting in an increased need for effective thermal management strategies. During IC test, characterization and fault isolation similar conditions are established. In particular, during continuous loop device testing using an ATE for the purpose of fault isolation, there is a risk of device degradation and complete failure due to thermal overstress.

Similarly, numerous high speed, high power microprocessors may be utilized together for use in web-based volume data storage and internet service provider type server applications. Although the space constraints of such server based IC device applications are less restrictive than their cellular counterparts, the sheer number and density of microprocessors in a server room can far outstrip the thermal mitigation requirements of cellular systems. A standard single microprocessor IC device found in server applications may produce up to 200W during peak operation, with several hundred such processors in operation in either a mainframe or server farm configuration, resulting in a very high thermal density. As with other IC devices, during test, characterization and fault isolation similar operating conditions are established. There is a risk of device degradation and complete failure due to thermal overstress.

In addition to this, server based IC devices may have to meet very stringent robustness requirements in order to establish confidence in their long term, high reliability operation for critical applications such as web-based data storage and communications. Therefore, additional thermal mitigation and control requirements are placed upon these devices during all phases of test. In particular, thermal management must be in place allowing for a wide range of steady state temperature control during all phases of test and characterization. For example, server based IC devices may be tested at temperatures as low as −50 C and as high as +120 C to ensure high reliability under all possible conditions. Therefore, it may be beneficial for the same thermal management strategies to be in place during fault isolation in order to correctly diagnose and characterize faults which may occur under specific conditions.

This increased complexity and thermal density has led to additional testing of digital circuits and/or digital systems under more stringent conditions. Testing may be used to verify or test various parts of devices, such as pieces of hardware, software or a combination of both. Mode failure identification, fault isolation and failure analysis may depend on replication and detection of failure modes over the full range of environmental operating conditions where failure may occur.

Fault isolation techniques may include a multiplicity of methods which would benefit from such a thermal mitigation and control strategy. Examples may include, but are not limited to; Thermal imaging, emission site detection (photon, secondary electron, x-ray, etc) including in vacuum, electron beam induced voltage contrast, thermally induced voltage alteration (TIVA), light induced voltage alteration (LIVA), optical beam induced resistance change (OBIRCH), etc.

One approach to characterization and failure analysis of a digital device under test (DUT) is the use of Laser Voltage Probe (LVP) (usually with a microscope) or other optical systems with a Solid Immersion Lens (SIL) or any air-gap lens. During device testing, self heating of the DUT may become problematic, especially under high frequency and high voltage test conditions. This is undesirable in that these heating effects, coupled with physical interaction by the probing system (optical, LEED, etc.), may result in perturbation of the device operation such that unwanted shifts in performance are observed, yielding invalid test results. In the worst case, a device may fail completely under testing due to overheating and/or thermal runaway caused at least in part by the LVP or other optical-type probes.

While this is somewhat of an issue for mobile devices, it may also pose a serious issue for the debug and characterization of high powered/high frequency multi-cored processors, such as those applicable to servers. Additionally, in the case of certain analytical equipment (e.g., infrared emission microscopy (IREM), thermal camera) excessive heat may also result in detector saturation and thus, device cooling may provide benefits at a system level as well. A basic solution to this problem is to provide a cooling mechanism to allow the device to be tested at maximum power and frequency without device failure or damage.

At present, two primary methods of device cooling are available: direct fluid spray cooling and direct air spray cooling. Neither of these solutions is without limitation, nor do they provide a solution suitable for all available analytical fault isolation or characterization techniques. For example, neither method would be acceptable in the instance of an analysis technique which must take place within a vacuum environment. Therefore, there is a need in the art for a solution to these shortcomings. For example, some analytical characterizations systems are preferably operable in vacuum, so therefore a cooling means is sought that can operate in vacuum as well as ambient conditions.

### SUMMARY

In a first aspect of the disclosure, an apparatus includes an electrically insulating thermally conductive carrier for supporting a device under test (DUT), one or more thermo-electric devices arranged with the carrier, and one or more conductive vias in the carrier to make electrical connection to the DUT for coupling to an external test apparatus.

In a second aspect of the disclosure, an apparatus includes electrically insulating thermally conductive carrier means for supporting a device under test (DUT), one or more solid state device means arranged with the carrier means for generating at least one of heat and cold, and one or more conductive means through the carrier means to make electrical connection to the DUT for coupling to an external test apparatus.

In a third aspect of the disclosure, a method of testing a device under test (DUT includes supporting the DUT on an electrically insulating thermally conductive carrier, arranging one or more thermo-electric devices coupled to the carrier to control the temperature of the DUT, connecting the DUT electrically to an external test apparatus through one or more conductive vias in the carrier, connecting the one or more thermo-electric devices to the external test apparatus, and characterizing with the external apparatus the DUT on the basis of the temperature of the DUT.

In a fourth aspect of the disclosure, a non-transitory computer readable media including program instructions which when executed by a processor cause the processor to perform the method, including the steps of controlling one or more thermo-electric devices coupled to a carrier to control the temperature of a device under test (DUT) arranged with the carrier, and characterizing the DUT with an external test apparatus through electrical connections between the DUT and the external test apparatus, the electrical connections including conductive vias in the carrier coupled to the DUT, and a flat top socket coupled to the vias in the carrier and to the external test apparatus.

### BRIEF DESCRIPTION OF THE DRAWINGS

FIG. 1 illustrates one configuration of a wireless communication system, in accordance with certain embodiments of the disclosure.

FIG. 2 is a perspective illustration of a carrier printed circuit board in accordance with certain embodiments of the disclosure.

FIG. 3 is a perspective detail illustration of conductive through vias in the carrier printed circuit board in accordance with certain embodiments of the disclosure.

FIG. 4 is an exploded perspective illustration of a carrier printed circuit board with added thermal masses and a flat top socket with integral cooling channels in accordance with certain embodiments of the disclosure.

FIG. 5 is an exploded perspective illustration of a carrier printed circuit board with a thermal heat transfer finger in accordance with certain embodiments of the disclosure.

FIG. 6 is a schematic side-view illustration of an apparatus for testing an integrated circuit DUT in accordance with certain embodiments of the disclosure.

### DETAILED DESCRIPTION

Various aspects are now described with reference to the drawings. In the following description, for purposes of explanation, numerous specific details are set forth in order to provide a thorough understanding of one or more aspects. It may be evident; however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Furthermore, various aspects are described herein in connection with a terminal, which can be a wired terminal or a wireless terminal. A terminal can also be called a system, device, subscriber unit, subscriber station, mobile station, mobile, mobile device, remote station, remote terminal, access terminal, user terminal, communication device, user agent, user device, or user equipment (UE). A wireless terminal may be a cellular telephone, a satellite phone, a cordless telephone, a Session Initiation Protocol (SIP) phone, a wireless local loop (WLL) station, a personal digital assistant (PDA), a handheld device having wireless connection capability, a computing device, or other processing devices connected to a wireless modem. Moreover, various aspects are described herein in connection with a base station. A base station may be utilized for communicating with wireless terminal(s) and may also be referred to as an access point, a Node B, or some other terminology.

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The techniques described herein may be used for various wireless communication networks such as Code Division Multiple Access (CDMA) networks, Time Division Multiple Access (TDMA) networks, Frequency Division Multiple Access (FDMA) networks, Orthogonal FDMA (OFDMA) networks, Single-Carrier FDMA (SC-FDMA) networks, etc. The terms “networks” and “systems” are often used interchangeably. A CDMA network may implement a radio technology such as Universal Terrestrial Radio Access (UTRA), CDMA2000, etc. UTRA includes Wideband CDMA (W-CDMA). CDMA2000 covers IS-2000, IS-95 and technology such as Global System for Mobile Communication (GSM).

An OFDMA network may implement a radio technology such as Evolved UTRA (E-UTRA), the Institute of Electrical and Electronics Engineers (IEEE) 802.11, IEEE 802.16, IEEE 802.20, Flash-OFDAM®, etc. UTRA, E-UTRA, and GSM are part of Universal Mobile Telecommunication System (UMTS). Long Term Evolution (LTE) is a release of UMTS that uses E-UTRA. UTRA, E-UTRA, GSM, UMTS, and LTE are described in documents from an organization named “3^{rd} Generation Partnership Project” (3GPP). CDMA2000 is described in documents from an organization named “3^{rd} Generation Partnership Project 2” (3GPP2). These various radio technologies and standards are known in the art. For clarity, certain aspects of the techniques are described below for LTE, and LTE terminology is used in much of the description below. It should be noted that the LTE terminology is used by way of illustration and the scope of the disclosure is not limited to LTE. Rather, the techniques described herein may be utilized in various application involving wireless transmissions, such as personal area networks (PANs), body area networks (BANs), location, Bluetooth, GPS, UWB, RFID, and the like. Further, the techniques may also be utilized in wired systems, such as cable modems, fiber-based systems, and the like.

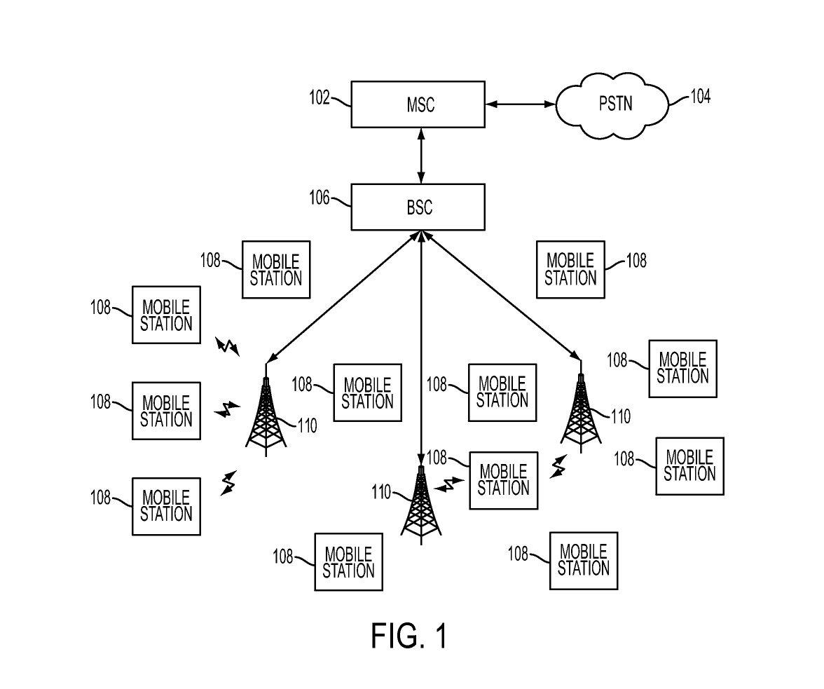

FIG. 1 illustrates a wireless system 100 that may include a plurality of mobile stations 108, a plurality of base stations 110, a base station controller (BSC) 106, and a mobile switching center (MSC) 102. The system 100 may be GSM, EDGE, WCDMA, CDMA, etc. The MSC 102 may be configured to interface with a public switched telephone network (PTSN) 104. The MSC may also be configured to interface with the BSC 306. There may be more than one BSC 106 in the system 300. Each base station 110 may include at least one sector, where each sector may have an omnidirectional antenna or an antenna pointed in a particular direction radially away from the base stations 110. Alternatively, each sector may include two antennas for diversity reception. Each base station 110 may be designed to support a plurality of frequency assignments. The intersection of a sector and a frequency assignment may be referred to as a channel. The mobile stations 108 may include cellular or portable communication system (PCS) telephones.

During operation of the cellular telephone system 100, the base stations 110 may receive sets of reverse link signals from sets of mobile stations 108. The mobile stations 108 may be involved in telephone calls or other communications. Each reverse link signal received by a given base station 110 may be processed within that base station 110. The resulting data may be forwarded to the BSC 106. The BSC 106 may provide call resource allocation and mobility management functionality including the orchestration of soft handoffs between base stations 110. The BSC 106 may also route the received data to the MSC 102, which provides additional routing services for interfacing with the PSTN 104. Similarly, the PTSN 104 may interface with the MSC 102, and the MSC 102 may interface with the BSC 106, which in turn may control the base stations 110 to transmit sets of forward link signals to sets of mobile stations 108.

This disclosure concerns itself with a high thermal conductivity material based DUT carrier PCB and a programmable, solid state cooling device, or devices, which can also be augmented with supplementary closed loop fluid cooling that is integrated into an equally high thermally conductive material based flat top socket interface. Specifically, the DUT is mounted on a carrier board (carrier PCB) with “through via electrical connections” matching that of the DUT. The carrier PCB is mounted to a flat top socket (FTS), which then mates the carrier PCB/DUT assembly to the test head. The combination of carrier PCB and DUT provides a rigid interface between the test head's load board and the SIL of the LVP or other similar fault isolation and characterization systems. This may be necessary since the SIL is in direct contact with the DUT. It should be appreciated that in this configuration, the DUT is fully or partially de-encapsulated and that the exposed area of the IC must remain unobstructed in order to allow probing or allow detection from various circuits within the DUT and to obtain a signal for analysis. Therefore, any cooling apparatus may preferably not interfere with or obstruct the fully exposed DUT surface area in any way.

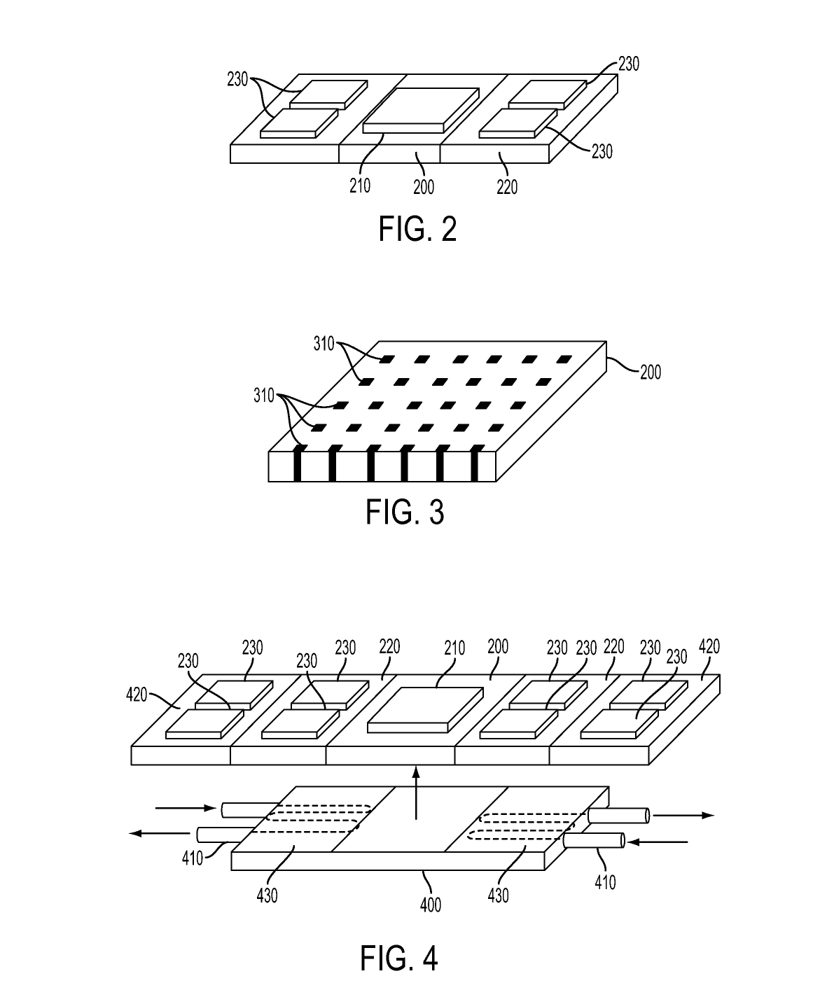

FIG. 2 illustrates a perspective view of a carrier substrate PCB 200 for controlling the temperature of a DUT 210. The carrier substrate PCB 200 is preferably constructed of a material with a high thermal conductivity (for example, Si and a ceramic such as AlN, Al₂O₃, and equivalents and combinations thereof) to assist in the transfer of heat away from the DUT 210, which is mounted on the carrier PCB 200. The carrier PCB 200 can be coated with a metal 220 of high thermal conductivity (e.g., copper and/or molybdenum).

Solid state thermo-electric cooler/thermo-electric heater (TEC/TEH) devices 230 can be mounted to the metallized carrier PCB 200 to provide device cooling or heating as required. The DUT 210 may be (backside) polished to thin the silicon substrate to within acceptable thicknesses for probing and other fault isolation and characterization techniques. A slight gap may exist between the remaining encapsulation of the DUT 210 and carrier PCB surface metallization 220. The slight gap is bridged with a high thermal conductivity metallic paint or paste (such as standard silver paint, not shown), thus completing the heat transfer path between the DUT 210 and the TEC/TEH 230 mounted on the carrier PCB 200. One or more TEC/TEHs 230 can be mounted depending on the power requirements of the DUT 210.

FIG. 3 illustrates, in a perspective view, details of through via electrical connections 310, or vias 310, in PCB 200 for matching connections on the DUT 210, which may be mounted face down to the FTS (not shown) for electrical connection to an external test apparatus, such as automated test equipment (ATE) (not shown).

Alternatively, during preparation of the DUT 210, further encapsulation may be removed by polishing the sides to expose unused circuitry allowing a direct thermal connection inside the device, raising the heat transfer efficiency. The TEC/TEHs 230 can be precisely controlled so that not only heat removal may be accomplished, but controlled device heating under quiescent conditions, extreme cooling or heating under nominal conditions, and nominal temperature control under full power conditions, as well as all combination of conditions in between, may be achieved for a full range of performance characterization.

A desired temperature of the DUT 210 may be monitored and controlled by enabling temperature sensors, such as thermistors, embedded in the DUT 210 and on the external carrier PCB 200 or FTS mounted thermocouples integrated for providing feedback for control of the TEC/TEHs 230. In another embodiment, the carrier PCB 200 may be constructed of standard PCB material or any other suitable material which is metallized and having one or more TEC/TEHs 230 mounted to achieve precise cooling or heating. The bridging method from DUT to metallization and TEC/TEH 230 is the same as described above. Additionally, excess cooling or heating can be achieved by addition of more, or higher power, TEC/TEHs 230 in order to overcome any reduction of heat transfer through the carrier PCB 200 itself or to simply accommodate higher power devices. For example, if 200 W of heat removal is required to dissipate 40 W of power from the DUT 210 due to inefficiencies in the thermal conductance path, multiple Peltier-type TEC/TEHs 230 may be added to accomplish the required cooling. The size and number of TEC/TEHs 230 is only limited by the potential size of the carrier PCB 200 itself which can be many times larger than the DUT 210, especially in the case of multi-core processors (e.g., in server devices) where only one or two devices may be mounted at a time for testing. Additionally, both sides of the carrier PCB 200 can be metallized so that TEC/TEHs 230 can be mounted on both sides. Known, TEC/TEHs 230 capable of about 130 W or more of cooling each (for example) are commercially available and may accommodate an appropriately sized carrier PCB 200 such that, for example, a total of 260 W of cooling for a 60 W DUT 210 is feasible. The wattages cited are for illustrative purposes only, and higher or lower power dissipation or generation may be accomplished by selection of an appropriate type and number of TEC/TEHs 230 for the test conditions.

It may be appreciated that the apparatus described is substantially uniformly temperature controlled (i.e., either for cooling or heating) throughout, not just at the DUT 210, as there is insufficient thermal path through electrical connections only, but sufficient thermal path through the carrier PCB 200 and metallization 220 may be provided with this arrangement. Furthermore, the DUT 210 may be connected to the flat-top socket by vias 310 through the carrier PCB 200, and where the through vias 310 are electrically isolated by the ceramic or other insulating base material of the PCB carrier 200.

FIG. 4 illustrates, in perspective, another embodiment. The flat top socket (FTS) 400, to which the carrier PCB 200/DUT 210 assembly is mounted and is used to interface to a testing fixture, is also constructed of a material with a high thermal conductivity (e.g., Si, and/or ceramic AlN and Al₂O₃) which may also contain integral cooling channels 410 through which closed loop, cooled fluid can circulate. The FTS 400 may also be metallized to allow effective heat transfer from the carrier PCB 200 in order to provide increased heat removal capability beyond that provided by the solid state TEC/TEHs 230 alone. This may be especially useful in the case of multiple high power devices or stacked devices.

In another embodiment, the FTS 400 may be constructed of standard plastic or any other suitable material which is metallized and which can augment the removal of heat from the DUT 210 and carrier PCB 200 in the same way as described above. Cooling flow through the FTS 400 could also comprise a multiplicity of cooling media such as water, oil, liquid nitrogen (LN₂) or other refrigerants, for example.

Additional thermal mass for heat transfer may be added to boost cooling/heating temperature control. For example, additional thermally conductive blocks 420 (or plates) made, for example, of copper, may be bonded to the PCB 200, on which additional Peltier-type TEC/TEHs 230 can be mounted (on both top and bottom, if desired, and space permits). Where the carrier PCB 200 is ceramic, the bonding method may be brazing. For other carrier materials and/or other high thermal conductivity masses, other more appropriate bonding methods may be used. As described above, the FTS 400 may be channeled internally for cooling flow, and metallization 430 (e.g., copper, molybdenum) may provide improved thermal contact to the PCB 200. Furthermore, the DUT 210 is still connected to the FTS 400 by vias 310 through the PCB 200, so there may be no impact on the configuration of the FTS 400.

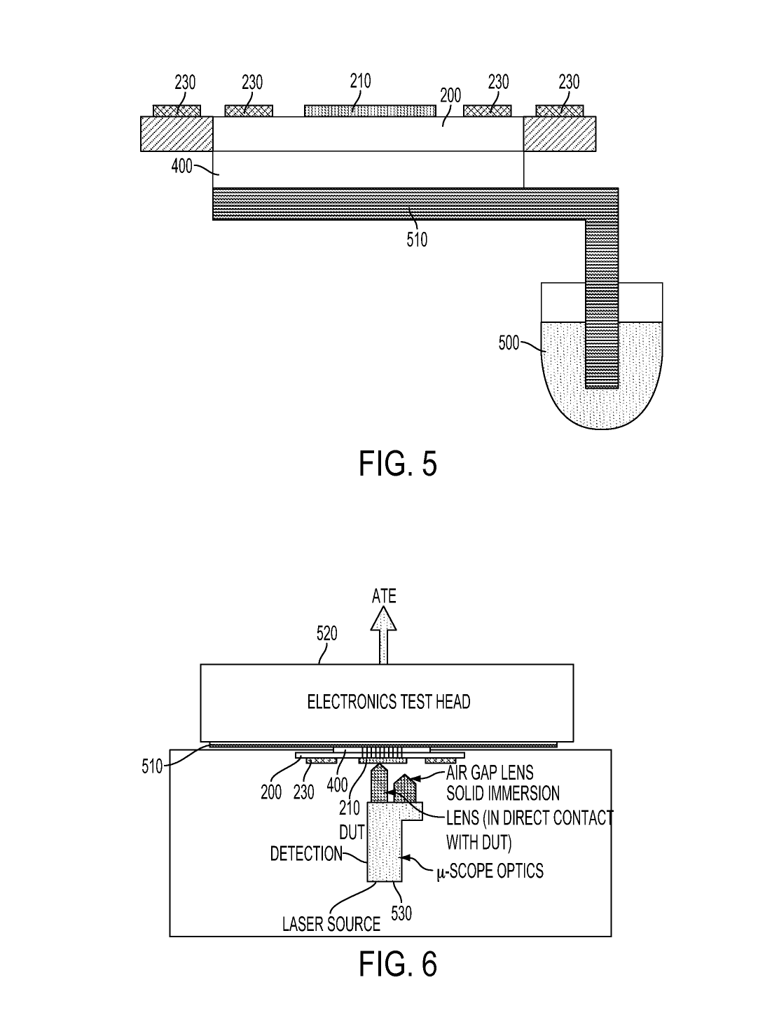

In yet another embodiment, as shown in a schematic view in FIG. 5, the FTS 400 may have no fluid cooling channels, but is connected to a remote LN₂ cryogenic source 500 (e.g., a LN₂ dewar) by an insulated “cold finger” 510 with high thermal conductivity, thereby providing substantial cooling with no direct fluid coolant required and reduced potential for undesirable vibration.

It may be appreciated that several disadvantages in current available cooling methods may be overcome, and several advantages not achievable with the current available cooling methods may be obtained. For example, there is no risk of electrical shorting of either the DUT 210 or system electronics that may occur with open fluid spray cooling. No special dielectric fluid is required to prevent electrical shorting as described above when direct spray cooling is used. Such coolants also may not be environmentally unfriendly and/or may include toxic fluorine based chemicals.

A system reconfiguration may not be required to accommodate the solid state cooling solution. Neither air spray nor other fluid spray cooling may effectively provide a method of heating the DUT 210 such as that which may be provided by a solid state device (e.g., the TEC/TEH 230). Furthermore, neither air spray nor other fluid spray cooling may be capable of providing a wide range of precise electronically controlled temperature (such as with a TEC/TEH 230 and a controller unit). The achievable precision may be to within a degree C. using a feedback loop based on embedded thermistor, thermocouple or other temperature sensor output. Whether in the case of solid state cooling/heating alone with TEC/TEHs 230, or in conjunction with an LN₂/cold finger cooled FTS 400, there is no risk of coolant leakage or added vibration from high velocity air flow or fluid spray flow, which may potentially reduce the resolution and accuracy of the probing LVP microscope. Still furthermore, the LVP system detector performance may be extended and maximized by increasing the temperature range of testing to saturation and failure conditions.

FIG. 6 is a schematic side-view illustration of an apparatus for testing an integrated circuit DUT 210 to characterize failure modes using an optical probe instrument such as, for example, an LVP with SIL, and including means for temperature control of the DUT 210. However, other probe instruments may include, but are not limited to, low energy electron diffraction (LEED), electron microscopy, ion bombardment spectroscopy, and the like.

In an embodiment of the apparatus, the FTS 400 is attached to a load board 510, which may have a standard layout for interfacing to an electronic test head 520 of an ATE (not shown). The PCB 200 may attach to the FTS 400 and, as described above, the DUT 210 may attach to the PCB 200, where the PCB 200 includes the DUT 210 and TEC/TEHs 230 attached thereon. The DUT 210 is arranged “face down,” i.e., with the electronic circuitry facing the PCB 200 and appropriately contacting electrical feed through vias 310 in the PCB 200, where the vias 310 are further appropriately coupled to vias in the FTS 400 for electrical connection to the electronic test head 520.

In the example of using an LVP 530, a laser source may probe the back surface of the thinned DUT 210 through either a solid immersion lens (SIL) in direct contact with the DUT 210, or through an air gap lens that is non-contact.

It may be appreciated that the combination of using a standard ATE with an adaptor means (i.e. a flat top socket FTS 400) to interface a carrier PCB 200 that includes indirect means for temperature controlling a DUT 210 (i.e., with thermally conductive coupling between the DUT 210 and the TEC/TEHs 230 through the carrier PCB 200) and simultaneously obtain quantitative optical imaging characterization of circuit performance from the thinned back of the DUT 210 may provide dynamic fault detection and failure analysis information over a full range of operating conditions not easily available otherwise.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented. It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An apparatus comprising:
an electrically insulating thermally conductive carrier for supporting a device under test (DUT);
one or more thermo-electric devices arranged with the carrier; and
one or more conductive vias in the carrier to make electrical connection to the DUT for coupling to an external test apparatus.

2. The apparatus of claim 1, further comprising metallization on the carrier between the thermo-electric devices and the carrier for thermal conductivity.

3. The apparatus of claim 1, further comprising thermally conductive metal blocks brazed to the ceramic carrier, the metal blocks supporting one or more other thermo-electric devices.

4. The apparatus of claim 3, further comprising:
one or more temperature sensors coupled to the at least one of the carrier and the blocks; and
a controller coupled to the one or more temperature sensors and the thermo-electric devices to control the temperature of the thermo-electric devices according to signals received by the controller from the temperature sensors.

5. The apparatus of claim 1, wherein the carrier comprises at least one of Si, SiO₂, ceramic AlN and ceramic Al₂O₃.

6. The apparatus of claim 1, further comprising a flat top socket configured to interface electrically to the DUT by connection with the one or more conductive vias through the carrier, wherein the flat top socket is configured to couple to the external test equipment.

7. The apparatus of claim 6, further comprising one or more channels in the flat top socket arranged to remove or increase heat from the carrier generated by one or more of the DUT and thermoelectric devices by fluid flow in the channels.

8. The apparatus of claim 6, further comprising a thermally conductive finger coupled to the flat top socket and to a source of at least one of heat and cold.

9. The apparatus of claim 8, further comprising:
temperature sensors embedded in at least one of the carrier and the flat top socket; and
a controller coupled to the source to control the temperature of the finger on the basis of signals received by the controller from the temperature sensors.

10. The apparatus of claim 1, further comprising an analytical device arranged with the DUT to characterize the DUT on the basis of signals generated by the external test apparatus.

11. The apparatus of claim 10, wherein the analytical device is at least one of a laser voltage probe, an infrared emission microscope and low energy electron diffraction (LEED).

12. A method of testing a device under test (DUT), comprising:
supporting the DUT on an electrically insulating thermally conductive carrier;
arranging one or more thermo-electric devices coupled to the carrier to control the temperature of the DUT;
connecting the DUT electrically to an external test apparatus through one or more conductive vias in the carrier;
connecting the one or more thermo-electric devices to the external test apparatus; and
characterizing with the external apparatus the DUT on the basis of the temperature of the DUT.

13. The method of claim 12, further comprising metalizing the carrier between the thermo-electric devices and the carrier for thermal conductivity.

14. The method of claim 12, further comprising brazing thermally conductive metal blocks to the ceramic carrier, the metal blocks supporting one or more other thermo-electric devices.

15. The method of claim 14, further comprising:
coupling one or more temperature sensors to the at least one of the carrier and the blocks; and
controlling the temperature of the thermo-electric devices with a controller coupled to the thermo-electric devices according to signals received by the controller from the temperature sensors.

16. The method of claim 12, further comprising interfacing the DUT electrically to a flat top socket by connection with the one or more conductive vias through the carrier, wherein the flat top socket is configured to couple to the external test equipment.

17. The method of claim 16, further comprising removing at least one of heat and cold from the carrier generated by one or more of the DUT and thermoelectric devices by fluid flow in channels in the flat top socket.

18. The method of claim 16, further comprising coupling a thermally conductive finger to the flat top socket and to a source of at least one of heat and cold.

19. The method of claim 18, further comprising:
embedding temperature sensors in at least one of the carrier and the flat top socket; and
controlling the temperature of the finger using a controller coupled to the source on the basis of signals received by the controller from the temperature sensors.

20. The method of claim 12, wherein the characterizing comprises:
arranging an analytical device with the DUT; wherein the analytical device is at least one of a laser voltage probe, an infrared-emission microscope and low energy electron diffraction (LEED), and
detecting signals using the analytical device on the basis signals generated by the external test apparatus.
